(19) United States
(12) Patent Application Publication
(10) Pub. No.: US 2018/0205197 A1
(43) Pub. Date: Jul. 19, 2018

(54) OPEN-LOOP WAVELENGTH SELECTIVE EXTERNAL RESONATOR AND BEAM COMBINING SYSTEM

(71) Applicant: TRUMPF Laser GmbH (TLS), Schramberg (DE)

(72) Inventors: Hagen Zimer, Dunningen-Seedorf (DE); Alexander Killi, Trossingen (DE); Christoph Tillkorn, Villingendorf (DE); Steffen Ried, Rottweil (DE)

(21) Appl. No.: 14/521,487

(22) Filed: Oct. 23, 2014

(51) Int. Cl. H01S 3/139; H01S 3/082; H01S 3/23; H01S 5/00; H01S 5/14; H01S 5/40

(52) U.S. Cl. CPC H01S 3/139; H01S 3/0826; H01S 3/2391; H01S 5/4068; H01S 5/141; H01S 5/4012; H01S 5/005

(57) ABSTRACT

A variety of dense wavelength beam combining (DWBC) apparatuses are described herein that combine a plurality of individual input beams into a single output beam. DWBC apparatuses contemplated herein are open-loop configurations, i.e. configurations where the wavelength selective optics of a feedback generation system are decoupled from abeam combining system that combines a plurality of input beams each having a wavelength selected from a range of different wavelengths. Specifically, each constituent beam of the combined output beam produced by the beam combining system traverses an optical path that does not include the wavelength-selective optics of the feedback generation system. DWBC apparatuses contemplated herein further provide for matching the wavelength-dependent angular dispersion functions of optics of the feedback generation system with the wavelength-dependent angular dispersion functions of optics of the beam combining system.

### TECHNOLOGY FIELD

The present disclosure relates generally to laser systems and more particularly to systems and methods for narrow-bandwidth laser beam stabilization and multiple laser beam combining.

### BACKGROUND

Dense wavelength beam combining (DWBC) techniques spatially superimpose a plurality of relatively low power input beams to produce a single high power output beam. In order to ensure that the high power output beam is of high quality, DWBC require wavelength-locking of each individual emitter. Wavelength-locking refers to forcing a substantial majority of radiation emitted by an emitter to be of wavelengths that fall within a narrow desired wavelength spectrum. DWBC systems achieve wavelength-locking of each individual emitter by providing wavelength-selective feedback. Wavelength-selective feedback stimulates emission of radiation at the desired wavelengths, which crowds out radiation at undesired wavelengths. DWBC systems can utilize a resonator cavity external to the resonator cavities of the individual emitters to provide the wavelength-selective feedback to.

Without wavelength-selective feedback, individual emitters in DWBC systems will emit intolerable levels of radiation at non-desired wavelengths. Radiation having non-desired wavelengths cannot be combined into a single beam by use of spectral-angular dispersive elements, e.g. diffraction gratings. As many DWBC systems operate as an inverse spectrometer, the wavelength-selective feedback—and the radiation emitted by the individual emitters—need to be extremely stable under changing environmental conditions. Additionally, radiation having non-desired wavelengths can induce temporal fluctuation in the output power by means of spectral crosstalk between neighboring emitters. Spectral crosstalk refers the situation where a portion of the radiation emitted by a first individual emitter is directed into a second individual emitter as feedback.

In order to limit the levels of radiation emitted at non-desired wavelengths, DWBC systems can incorporate wavelength filtering cavities designed to remove radiation having non-desired wavelengths from the low power input beams—or components thereof—as they propagate through the wavelength filtering cavities. However, spatial filtering is a lossy procedure that can cause a significant reduction in the efficiency of the DWBC systems. In order to limit the reduction in efficiency attributable to special filtering, some DWBC systems perform spatial filtering in a low-power region of an external cavity.

### SUMMARY OF THE INVENTION

A variety of dense wavelength beam combining (DWBC) apparatuses are described herein that combine a plurality of individual input beams into a single output beam. DWBC apparatuses contemplated herein are open-loop configurations, i.e. configurations where the wavelength selective optics of a feedback generation system are decoupled from a beam combining system that combines a plurality of input beams each having a wavelength selected from a range of different wavelengths. Specifically, each constituent beam of the combined output beam produced by the beam combining system traverses an optical path that does not include the wavelength-selective optics of the feedback generation system. Therefore, DWBC apparatuses contemplated herein perform spatial filtering in a low-power region of an external cavity.

DWBC apparatuses contemplated herein further utilize a first angular provide for matching the wavelength-dependent angular dispersion functions of optics of the feedback generation system with the wavelength-dependent angular dispersion functions of optics of the beam combining system. As a result, the quality of the output beam produced by the DWBC systems contemplated herein is not compromised by a mismatch in the angular dispersive characteristics of the feedback generation system and the beam combining system.

An external cavity laser apparatus is provided that includes a plurality of beam emitters that collectively emit a plurality of external cavity input beams each having a primary component with an initial linear polarization state, a beam splitter disposed in an optical path of the plurality of input beams and configured to extract, from the plurality of external cavity input beams, a plurality of first extracted component beams and to direct the plurality of first extracted component beams into a feedback branch, a reflective element disposed in the feedback branch and configured to reflect the plurality of first extracted component beams back through the beam splitter such that at least a portion of the plurality of first extracted component beams is transmitted into the plurality of beam emitters as a plurality of orthogonal feedback component beams each having a polarization state that is orthogonal to the initial linear polarization state, and a first angular dispersive optic disposed in the feedback branch and having a first wavelength-dependent angular dispersion function, the first angular dispersive optics being configured to impart a wavelength-dependent angular spectrum determined by the first wavelength-dependent angular dispersion function on the plurality of first extracted component beams.

A method is provided for stabilizing the wavelengths of a plurality of input beams collectively emitted by a plurality of emitters, each of the plurality of input beams having a primary component with an initial linear polarization state. The method involves extracting from the plurality of input beams a plurality of extracted component beams, directing the plurality of extracted component beams through an angular dispersive optic that imparts a wavelength-dependent angular spectrum to the plurality of extracted component beams, directing the plurality of extracted component beams through a feedback branch that includes a wavelength selective optic so as to provide a plurality of feedback beams that each includes a component that has a polarization state that is orthogonal to the initial linear polarization state of the plurality of input beams; and directing the plurality of feedback beams into the plurality of emitters.

A method is provided for producing a combined output beam formed from a plurality of beam combining input beams extracted from a plurality of linearly-polarized laser source output beams collectively emitted by a plurality of emitters, each of the plurality of laser source output beams having a primary component with an initial linear polarization state. The method involves extracting from the plurality of input beams a plurality of extracted component beams and the plurality of beam combining input beams, directing the plurality of extracted component beams through an angular dispersive optic that imparts a wavelength-dependent angular spectrum to the plurality of extracted component beams, directing the plurality of extracted component beams through a feedback branch that includes a wavelength selective optic so as to provide a plurality of feedback beams that each includes a component that has a polarization state that is orthogonal to the initial linear polarization state of the plurality of input beams, directing the plurality of feedback beams into the plurality of emitters, and providing the combined output beam by directing the plurality of beam combining input beams at an angular dispersive beam combining optic such that each of the plurality of beam combining input beams emerges from an overlap region of the angular dispersive beam combining optic with a common direction of propagation.

### BRIEF DESCRIPTION OF THE DRAWINGS

The present invention will be described in even greater detail below based on the exemplary figures. The invention is not limited to the exemplary embodiments. All features described and/or illustrated herein can be used alone or combined in different combinations in embodiments of the invention. The features and advantages of various embodiments of the present invention will become apparent by reading the following detailed description with reference to the attached drawings which illustrate the following:

FIG. 1 illustrates an apparatus for producing, via dense wavelength beam combining (DWBC) techniques, a single, multi-wavelength output laser beam comprising a plurality of spatially and directionally overlapped beams that each have a narrow wavelength spectrum;

FIG. 2 illustrates an alternative apparatus for producing, via dense wavelength beam combining techniques, a single, multi-wavelength output laser beam comprising a plurality of spatially and directionally overlapped beams that each has a narrow wavelength spectrum;

FIG. 3 illustrates an additional alternative apparatus for producing, via dense wavelength beam combining techniques, a single, multi-wavelength output laser beam comprising a plurality of spatially and directionally overlapped beams that each has a narrow wavelength spectrum;

FIGS. 4A and 4B illustrate configurations of laser sources for use in an external cavity laser apparatus wherein the laser sources are arrays of diode lasers formed from horizontal stacks of diode bars;

FIGS. 5A, 5B, and 5C illustrate configurations of laser sources for use in an external cavity laser apparatus wherein the laser sources are arrays of diode lasers formed from vertical stacks of diode bars; and

FIG. 6 illustrates a configuration of a laser source for use in an external cavity laser apparatus wherein the laser source is an array of diode lasers formed from a two-dimensional stack of diode bars.

### DETAILED DESCRIPTION OF THE DRAWINGS

The present disclosure describes a variety of dense wavelength beam combining (DWBC) systems that combine a plurality of individual input beams into a single output beam. The DWBC systems contemplated herein are open-loop configurations, i.e. configurations where the wavelength selective optics of a feedback-generation system (which can also be referred to as a wavelength stabilization system) are decoupled from the beam combining system. Specifically, each constituent beam of the combined output beam produced by the beam combining system traverses an optical path that does not include the wavelength-selective optics of the feedback generation system.

Performing spatial filtering and cross-talk mitigation in a low power region of an external cavity of a DWBC system limits the loss in output power attributable thereto. Therefore, as compared to configurations where the wavelength selective optics of the feedback component system form a portion of the optical path between the plurality of input beam emitters and the beam combining optic of the beam combining system (i.e. “closed-loop” configurations), open-loop configurations are capable of achieving significantly greater wall-plug efficiency.

Furthermore, in the DWBC systems contemplated herein, the angular dispersive behavior of the wavelength-selective optics of the feedback generation system is identical to the angular dispersive behavior of the beam combining optic of the beam combining system. Specifically, the wavelength selective optics of the feedback generation system and the beam combining components of the beam combining system have identical wavelength-angle dispersion functions (i.e. the relationship, defined for a range of wavelengths, between the wavelength of a beam and the difference between the beam's angles of incidence and transmission with respect to the optic). Therefore, for each wavelength in the range of wavelengths for which the wavelength-angle dispersion function is defined, the difference between the angle of incidence and the angle of transmission of a beam will be the same with respect to both the wavelength-selective optics of the feedback generation system and the beam combining optics of the beam combining system.

DWBC systems are described herein that utilize two identical optics as different systems components. One of the identical optics is used as a wavelength-selective component of the feedback generation system and one is used as a beam combining component of the beam combining system. In some of the systems contemplated herein the two identical optics are identical diffraction gratings. The use of identical optics in both the feedback generation system and the beam-combining system allows for seamless matching of the wavelength-angle-position spectrum of a light cone produced by an angular dispersive component of the wavelength selective element of the feedback generation system and the wavelength-angle-position spectrum of a light cone incident on an angular dispersive component of the beam combining system. As a result, output beam quality of the DWBC systems contemplated herein is not compromised by a mismatch in the angular dispersive characteristics of the feedback generation system and the beam combining system.

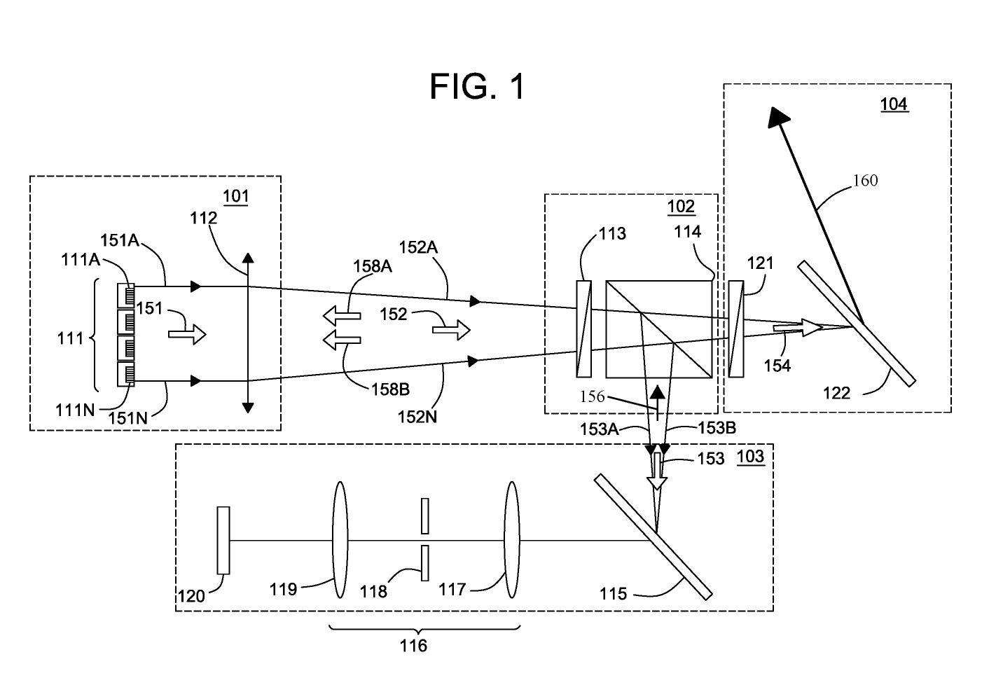

FIG. 1 illustrates an apparatus for producing, via dense wavelength beam combining (DWBC) techniques, a single, multi-wavelength output laser beam comprising a plurality of spatially and directionally overlapped single wavelength beams. The DWBC apparatus 100 includes an input generation system 101, an adjustable beam splitting system 102, a feedback generation system 103 and a beam combining system 104.

The input generation system 101 is a means for producing a plurality of individual beams that together constitute laser source output 151. The input generation system includes a laser source 111 (which includes a plurality of emitters) and a position-to-angle transform optic 112. The position-to-angle transform optic 112 may also be considered to be part of the feedback generation system 103 as it interacts with the laser source output 151 in a manner that impacts the downstream properties of the feedback generation system input 153. Similarly, the position-to-angle transform optic 112 may also be considered to be part of the beam combining system 104 as it interacts with the laser source output 151 in a manner that impacts the downstream properties of the beam combining system input 154.

The adjustable beam splitting system 102 is a means for splitting the beam splitting system input 152 into a feedback generation system input 153 and a beam combining system input 154 and also a means for directing the feedback generation system input 153 into the feedback generation system 103 and directing the beam combining system input 154 into the beam combining system 104. The adjustable beam splitting system 102 includes a means for selecting the fraction of optical power directed into the feedback generation system 103 and the fraction of optical power directed into the beam combining system 104. In the embodiment illustrated in FIG. 1, the adjustable beam splitting system 102 includes a polarizing beam splitter 114. However, in alternative embodiments, the adjustable beam splitting system 102 may include other means for splitting a input beams, e.g. a thin-film polarizer.

The feedback generation system 103 is a means for producing wavelength-stabilizing feedback 156, that when directed into the laser source 111 as feedback, serves to select, for each of the plurality of emitters of the laser source 111, a preferred resonant mode. The feedback generation system 103 can be identified by the optical path from the polarizing beam splitter 114 through an angular dispersive optic 115 to a reflective element 120 and from the reflective element 120 back to the polarizing beam splitter 114 in the reverse direction.

The beam combining system 104 is a means for producing a single multi-wavelength combined output beam (combined output beam 160) from a plurality of individual single-wavelength input beams that together constitute the beam combining system input 154. The beam combining system 104 can be identified by the optical path from the polarizing beam splitter 104 to an angular-dispersive beam combining optic 122 and into the optical path of the combined output beam 160.

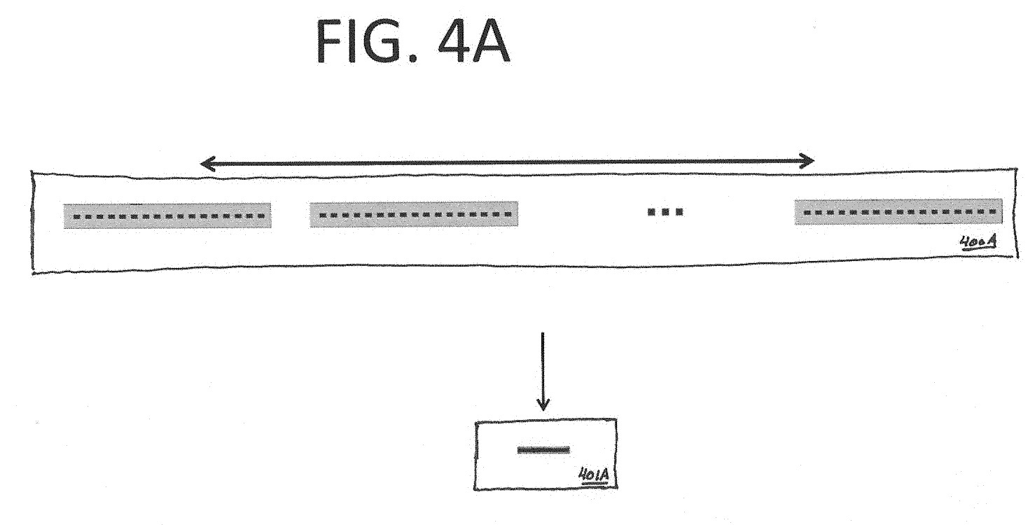

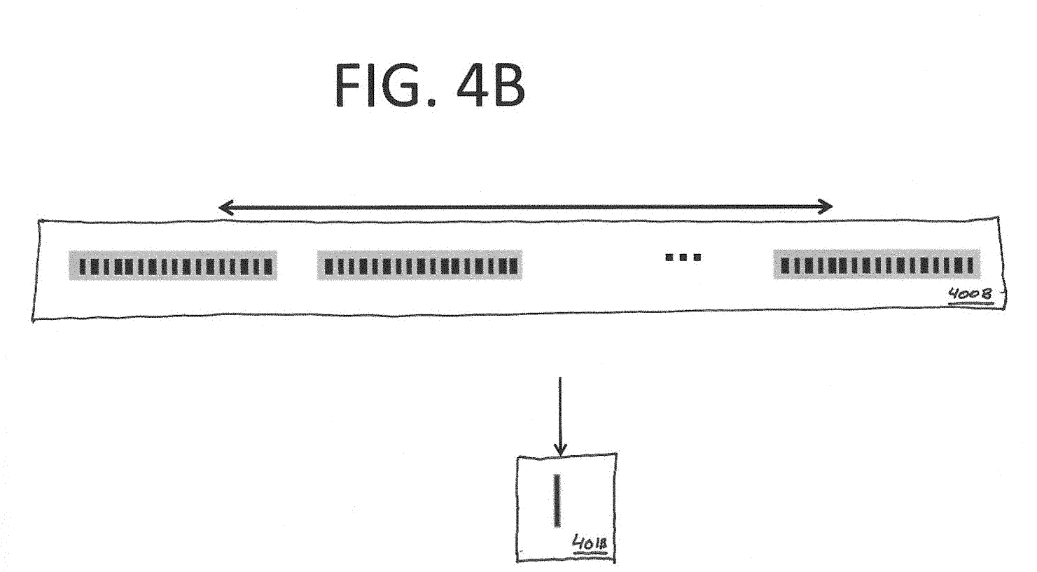

In the embodiment illustrated in FIG. 1, the laser source 111 includes a plurality of individual emitters (e.g. 111A and 111N) that each emit a single laser beam that is a constituent beam of the laser source output 151. Each constituent beam of the laser source output 151 may also be called an input beam. The individual laser emitters may be diode lasers, fiber lasers, solid-state lasers, or any other type of lasers. The plurality of individual emitters that together constitute the laser source 111 may be arranged in a one dimensional array, a two dimensional array, or a variety of other configurations. For example, laser source 111 may be an array of diode lasers formed from vertical or horizontal stacks of diode bars, each of which has a plurality of individual diode laser emitters. The laser source 111 may be any array of diode lasers configured as depicted in any of FIGS. 4A-B, 5A-C, and 6. However, the laser source 111 is not limited to such configurations, and embodiments described herein contemplate that a variety of alternative laser source configurations may be used as well. The configurations of the laser source 111 depicted in FIGS. 4A-B, 5A-C, and 6 may be any of a geometrically stacked configuration (a geometric stack), an optically stacked configuration (an optical stack), or any other means of configuring a plurality of beams as depicted in those FIGS.

Although not shown in the embodiment illustrated in FIG. 1, implementations contemplate that the input generation system 101 can include a variety of optics for manipulating the beams emitted by individual emitters of the laser source 111 prior to their interaction with the position-to-angle transform optic 112. Typically, beams emitted by diode lasers have an asymmetric beam profile, i.e. the beam diverges at disparate rates along two axes defined perpendicular to its direction of propagation. The two axes can be identified as a fast axis, along which the beam diverges more rapidly, and a slow axis, upon which the beam diverges comparatively more slowly. The manipulation of the beams may be referred to as preprocessing and can include, e.g., rotation of the beams such that downstream processing is performed along a fast axis rather than a slow axis, collimation of the beams along the fast axis, and collimation of the beams along the slow axis. A variety of prior art literature discusses techniques for preprocessing beams emitted by diode laser emitters, such as those of the laser source 111. For example, the beams emitted by the laser source 111 may be manipulated as described in U.S. patent application Ser. No. 14/053,187 or as describe in U.S. Pat. No. 8,724,222.

In the embodiment depicted in FIG. 1, each constituent beam of the system input 151 is substantially linearly-polarized. Each emitter of a diode array laser source, such as the laser source 111, emits a beam that theoretically consists only of a component that has an initial linear polarization. In various different reference frames, the initial linear polarization can be said to be a p-polarization, an s-polarization, or a combination of p-polarization and s-polarization. However, as a result of various factors (e.g. manufacturing defects), the emitters of a diode array laser source each emits a beam that may include an unpolarized component or that may include various components that have a polarization that is at an angle with respect to the theoretical initial linear polarization. Therefore, in practice, each beam emitted by an emitter in the laser source 111 may be described as including a primary component with an initial linear polarization and additional secondary components that can be characterized, at least at a particular instant in time, as unpolarized, elliptically polarized, or linearly polarized at an angle with respect to the initial linear polarization of the primary component. Such beams can be said to be primarily linearly polarized. A primarily linearly polarized beam is a beam in which a linearly polarized primary component carries at least 80% of the total optical power of the beam, preferably carries at least 90%, and particularly preferably carries at least 94%.

Typically, diode laser emitters are marketed as transverse electric (TE) or transverse magnetic (TM), where the TE or TM describes the manner in which the emitted beams are primarily linearly polarized. In the remaining discussion of FIG. 1, it is assumed that each constituent beam of the laser source output 151 is primarily p-polarized with respect to the principle plane of the polarizing beam splitter 114. However, embodiments herein contemplate that each constituent beam of the laser source output 151 can also be primarily s-polarized with respect to the principle plane of the polarizing beam splitter 114 or can be primarily linearly polarized in a direction that is neither entirely s-polarized or p-polarized with respect to the principle plane of the polarizing beam splitter 114.

Each emitter in the laser source 111 has a particular, fixed location with respect to the position-to-angle transform optic 112. Therefore, the laser source output 151 has a position spectrum that corresponds to the spatial distribution of the emitters in the laser source 111. For example, the position of constituent beam 151A of the laser source output 151 corresponds to the position of the individual emitter 111A, while the position of the constituent beam 151N of the laser source output 151 corresponds to the position of the individual emitter 111N.

The position-to-angle transform optic 112 transforms the position spectrum of the laser source output 151 into an angular spectrum of the beam splitting system input 152. In the embodiment depicted in FIG. 1, the angular spectrum of the beam splitting system input 152 refers to the set of angles of transmission with respect to the position-to-angle transform optic 112 of the beam splitting system input 152. The position-to-angle transform optic 112 converts a position of each constituent beam of the laser source output 151 (which corresponds to a position of an emitter of the laser source 111) into an angle of incidence with respect to the angular dispersive optics of both the feedback system (i.e. the angular dispersive optic 115) and the beam combining system (i.e. the angular dispersive beam combining optic 122). Specifically, the angular spectrum of the beam splitting system input 152 determines the set of angles of incidence, with respect to the angular dispersive optic 115 and the angular dispersive beam combining optic 122, of the constituent beams of the feedback generation system input 153 and the beam combining system input 154. Therefore, the feedback generation system input 153 and the beam combining system input 154 both have an angular spectrum that is determined by the angular spectrum of the beam splitting system input 152. For example, the position-to-angle transform optic 112 transforms a position of the constituent beam 151A into an angle of incidence with respect to the angular dispersive optic 115 (which is transferred to the constituent beam 153A of the feedback generation system input 153) and also transforms a position of the constituent beam 151A into an angle of incidence with respect to the angular-dispersive beam combining optic 122 (which is transferred to the constituent beam 154A of the beam combining system input 154).

The embodiment depicted in FIG. 1 eliminates a source of output beam quality degradation present in DWBC apparatuses in which a position-to-angle transform optic used to generate angles of incidence with respect to a feedback system angular dispersive optic is distinct from a position-to-angle transform optic used to generate angles of incidence with respect to a beam combining system angular dispersive optic. In such systems, slight differences in the distinct transform optics (even in such cases where the distinct transform optics are manufactured to identical specifications) can create slight differences in the angular spectrum they produce and thereby cause degradation in output beam quality. The embodiment depicted in FIG. 1 eliminates such output beam quality degradation attributable to differences falling within manufacturing tolerances of position-to-angle transform optics.

The adjustable beam splitting system 102 includes a birefringent optic 113 in addition to the polarizing beam splitter 114. In various embodiments, depending on the system design, the birefringent optic 113 may be, e.g., a half wave plate or a quarter wave plate. In the embodiment depicted in FIG. 1, the birefringent optic 113 is a half wave plate that rotates the polarization of the beam splitting system input 152. Specifically, the birefringent optic 113 rotates the primarily linear polarization of each constituent beam of the beam splitting system input 152. In other words, the birefringent optic 113 rotates the primarily linear polarization of the beam splitting system input 152 such that each beam emerging from the birefringent optic 113 has a linear polarization that can be represented as the sum of a p-polarized component and an s-polarized component (wherein p-polarized and s-polarized are defined with respect to the principle plane of the polarizing beam splitter). Therefore, in the embodiment illustrated in FIG. 1, the beam splitting system input 152, which includes substantially a primary p-polarized component, is converted by the birefringent optic 113 into a superimposed combination of an s-polarized component and a p-polarized component. As a result, after interacting with the birefringent optic 113, the beam splitting input 152 includes a plurality of altered input component beams that each includes a first altered input component beam (i.e. a constituent beam of the s-polarized component) and a second altered input component beam (i.e. a constituent beam of the p-polarized component).

The polarizing beam splitter 114 extracts, from each constituent beam of the beam splitting system input 152 a first extracted component beam and a second extracted component beam. The plurality of first extracted component beams collectively constitute the feedback generation system input 153 and the plurality of second component beams collectively constitute the beam combining system input 154. Specifically, the polarizing beam splitter 114 extracts, from the beam splitting system input 152, the s-polarized component and directs it into the feedback generation system 103 as the feedback generation system input 153. The polarizing beam splitter 114 also extracts the p-polarized component and directs it into the beam combining system 104 as the beam combining system input 154. In this manner, the adjustable beam splitting system 102 extracts first and second components of each input beam of the laser source output 151 and directs the first component into the feedback generation system 103 and the second component into the beam combining system 104.

The birefringent optic 113 can itself be rotated in order to adjust the fractions of the optical power of the beam splitting system input 152 that is directed to the feedback generation system 103 and to the beam combining system 104. Therefore, the birefringent optic 113 and the polarizing beam splitter 114 together provide an “adjustable” means for splitting each constituent beam of the beam splitting system input 152. The adjustability of the adjustable beam splitting system 102 enables the apparatus 100 to be adjusted to account for variations in the characteristics of the laser source 111. For example, if the laser source 111 includes individual diode lasers (which have a partially reflective element that defines an emitting end of an internal cavity) that provide a relatively high level of internal feedback, the birefringent optic 113 can be adjusted such that the amount of optical power provided to the feedback generation system 103 is relatively low in order to instead provide a greater level of optical power to the beam combining system 104.

In alternative embodiments, the birefringent optic 113 can be rotated at an angle such that it does not alter the primary component of the laser source output 151 and that allows the polarizing beam splitter 114 to couple secondary components of the laser source output 151 (i.e. components that can be characterized as unpolarized, elliptically polarized, or linearly polarized at an angle with respect to the initial linear polarization of the primary component) into the feedback generation system 103 as the feedback generation system input 153. Alternative embodiments that omit the birefringent optic 113 are also possible where the polarizing beam splitter is configured to direct the primary component of the laser source output 151 to the beam combining system 104 as the beam combining system input 154 and to direct any secondary components of the laser source output 151 into the feedback generation system 103 as feedback generation system input 153.

In practice, it is necessary to return less than 50% of the optical power produced by the laser source 111 as feedback and therefore necessary to direct less than 50% of the optical power produced by the laser source 111 into the feedback generation system 103. In order to achieve high operational efficiency of the DWBC system 100, it is preferable to return less than 15% of the optical power produced by the laser source 111 (i.e. of the optical power of the laser source output 151) as feedback and therefore necessary to direct less than 15% of the optical power produced by the laser source 111 into the feedback generation system 103. Through product testing and experimentation, it has been determined that optimal operation of the DWBC system 100 is achieved when approximately 4% to approximately 10% of optical power produced by the laser source 111 is directed into the feedback generation system 103.

The feedback generation system 103 includes a number of components that collectively select a wavelength-dependent angular spectrum for the wavelength-stabilizing feedback 156. Specifically, the components of the feedback generation system 103 collectively select, for each constituent beam of the wavelength-stabilizing feedback 156, a single allowed wavelength-angle combination. Each of the plurality of emitters of the laser source 111 emits a beam that includes a preferred resonant mode component and an alternative resonant mode component. The preferred resonant mode component of each constituent beam consists of photons having a wavelength that falls within a narrow spectral band that corresponds to a preferred resonant mode of an emitter of the laser source 111 that emitted the beam. The alternative resonant mode component of each constituent beam consists of photons having a wavelength that falls outside of the narrow spectral band that corresponds to the preferred resonant mode of the emitter of the laser source 111 that emitted the beam. A single wavelength-angle combination is selected for each constituent beam of the wavelength-stabilizing feedback 156 by removing components of the feedback generation system input 153 that do not correspond to a preferred resonant mode of one of the emitters of the laser source 111. In some embodiments, the removal of such components of the feedback generation system input 153 is achieved by a spatial filtering element, e.g., a hard aperture.

Each constituent beam of the laser source output 151 includes both a preferred resonant mode component and an alternative resonant mode component. Both components propagate through the system and are therefore included in constituent beams of the beam-splitting system input 152, the feedback generation system input 153, and the beam combining system input 154. When present in constituent beams of the beam combining system input 154, alternative resonant mode components degrade the quality of the combined output beam 160. Alternative resonant mode components will not be spatially and directionally overlapped upon emerging from the angular dispersive beam combining optic 122 but will instead possess a residual angular spectrum. The prevalence of alternative resonant mode components in constituent beams of the beam combining system input 154 is limited by taking the feedback generation system input 153 and removing the alternative resonant mode components to produce the wavelength stabilizing feedback 156. The feedback generation system 103 is a means of removing alternative resonant mode components from constituent beams to produce the wavelength stabilizing feedback 156, which is composed of constituent beams that each include only photons having a wavelength that falls within the narrow spectral band that corresponds to the preferred resonant mode of the emitter of the laser source 111 that emitted the beam.

The angular dispersive optic 115 of the feedback generation system 103 transforms the angular spectrum possessed by the feedback generation system input 153 (which was imparted by the position-to-angle transform optic 112) into a wavelength-dependent angular spectrum. Specifically, the angular dispersive optic 115 is disposed relative to the position-to-angle transform optic 112 such that the preferred resonant mode component of each constituent beam of the feedback generation system input 153 emerges from the angular dispersive optic with a common direction of propagation. In particular, the angular dispersive optic 115, the transform optic 112, and a spatial filtering element 116 are positioned relative to one another such that preferred resonant mode component of each constituent beam of the feedback generation system input 153 passes through the spatial filtering element 116 while the alternative resonant mode component of each constituent beam of the feedback generation system input 153 does not pass through the spatial filtering element 116 after emerging from the angular dispersive optic 115.

In the embodiment depicted in FIG. 1, the spatial filtering element 116 includes two position-to-angle transform optics 117 and 119 positioned about either side of an aperture 118 along the optical path between the angular dispersive optic 115 and a highly reflective mirror 120. The two position-to-angle transform optics 117 and 119 increase the fidelity with which the aperture 118 selects the preferred resonant mode components of the feedback generation system input 153 and filters out the alternative resonant mode components of the feedback generation system input 153. The position-to-angle transform optics 117 and 119 increase the fidelity with which the aperture 118 by magnifying the angular spectrum of the alternative resonant mode components of the feedback generation system input 153 and thereby ensuring that such components do not pass through the aperture 118. In alternative implementations, the spatial filtering element may be a waveguide structure, a set of mirrors that have a gradient layer, or any other component or set of components capable of filtering undesired alternative resonant mode components.

In alternative embodiments, the preferred resonant mode components of the feedback generation system input 153 can be selected without the use of the spatial filtering element 116 but instead by separating the angular dispersive optic 115 from the highly reflective mirror 120 by a sufficiently long optical path. In such embodiments, after emerging from the angular dispersive optic 115, the alternative resonant mode components of the feedback generation system input 153 diverge from the optical path prior to reaching the highly reflective mirror 120 and therefore are not reflected as components of the wavelength stabilizing feedback 156. In these alternative embodiments, the spatial filtering element 116, including e.g. an aperture, a waveguide structure, a set of mirrors that have a gradient layer, etc., can be omitted.

After emerging from the angular dispersive optic 115 for a first time, the preferred resonant mode component of each constituent beam of the feedback generation system input 153 travels through the spatial filtering element 116, reflects off of the highly reflective mirror 120, passes back through the spatial filtering element 116, and passes back through the angular dispersive optic 115. Upon exiting the angular dispersive optic 115, the preferred resonant mode components constitute the wavelength-stabilizing feedback 156. The wavelength stabilizing feedback 156 possesses a wavelength-dependent angular spectrum imparted by the angular dispersive optic 115. The wavelength-dependent angular spectrum imparted by the angular dispersive optic includes only wavelength-angle pairs that correspond to a preferred resonant mode of one of the emitters in the laser source 111.

After emerging from the angular dispersive optic 115, the wavelength stabilizing feedback 156, which retains the s-polarization state of the feedback generation system input 153, is reflected by the polarizing beam splitter 114 and directed towards the laser source 111 through the birefringent optic 113 and the position-to-angle transform optic 112. The birefringent optic 113 again rotates the polarization of the wavelength stabilizing feedback 156 to form an orthogonal wavelength stabilizing feedback component 158A (which is orthogonal to the primary component of the laser source output 151) and a parallel wavelength stabilizing feedback component 158B (which is parallel to the primary component of the laser source output 151). Therefore, upon passing through the birefringent optic 113, the wavelength stabilizing feedback 156 no longer consists entirely of s-polarized (as defined with respect to the principle plane of the polarizing beam splitter 114) constituent beams but instead consists of constituent beams that have a polarization state that is a superposition of an s-polarization state and a p-polarization state.

As a result of the optical power requirements of the feedback generation system 103, the optical power of the component of each constituent beam of the wavelength stabilizing feedback 156 that is polarized orthogonally to the constituent beam of the laser source output 151 from which it was extracted is necessarily greater than 50% of the optical power of the entire constituent beam of the wavelength stabilizing feedback 156. Specifically, the optical power of the orthogonal wavelength stabilizing feedback component 158A is necessarily greater than 50% of the optical power of the wavelength stabilizing feedback 156. In order to achieve high operational efficiency of the DWBC system 100, it is preferable that the optical power of the component of each constituent beam of the wavelength stabilizing feedback 156 that is polarized orthogonally to the constituent beam of the laser source output 151 from which it was extracted is necessarily greater than 85% of the optical power of the entire constituent beam of the wavelength stabilizing feedback 156 (i.e. the orthogonal wavelength stabilizing feedback component 158A is greater than 85% of the optical power of the wavelength stabilizing feedback 156). Product testing and experimentation have determined that optimal operation of the DWBC system 100 is achieved when the optical power of the component of each constituent beam of the wavelength stabilizing feedback 156 that is polarized orthogonally to the constituent beam of the laser source output 151 from which it was extracted is necessarily approximately 90%-98% of the optical power of the entire constituent beam of the wavelength stabilizing feedback 156 (i.e. the orthogonal wavelength stabilizing feedback component 158A is approximately 90%-98% of the optical power of the wavelength stabilizing feedback 156).

The position-to-angle transform optic 112 images the wavelength-stabilizing feedback 156 onto the laser source 111, i.e. the position-to-angle transform optic 112 converts the wavelength-dependent angular spectrum imparted by the angular dispersive optic 115 into a wavelength-position spectrum such that each constituent beam of the wavelength-stabilizing feedback is directed into the emitter in the laser source 111 that emitted the input beam from which it was extracted (i.e. the constituent beam of the laser source output 151 from which the constituent beam of the wavelength-stabilizing feedback was extracted). In this manner, each emitter (or channel) in the laser source 111 adjusts the wavelength of the constituent beam of the laser source output (or input beam) to the match the wavelength provided to it by the feedback generation system 103. While each channel adjusts to a single wavelength, the configuration does not preclude the possibility that multiple channels will each emit beams of the same wavelength. For example, in situations where the laser source is a stack of diode bars, it may be possible that individual emitters from different diode bars emit beams of the same wavelength.

The beam combining system 104 includes components that collectively superimpose the plurality of individual single-wavelength beams that each is a constituent beam of the beam combining system input 154 to produce the combined output beam 160. In the embodiment illustrated in FIG. 1, the beam combining system 104 includes half wave plate 121. Half wave plate 121 rotates the polarization of the beam combining system input 154 into an s-polarized state with respect to the principle plane of the angular dispersive beam combining optic 122 in order to improve the diffraction efficiency of the combined output beam 160 and the overall efficiency of the DWBC system.

The angular dispersive beam combining optic 122 applies a wavelength-angle dispersion function to the beam combining system input 154 to produce the combined output beam 160. The angular dispersive beam combining optic 122 is disposed relative to the position-to-angle transform optic 112 such that the wavelength-angle dispersion function applied by the beam combining optic 122 to the beam combining system input 154 results in each component beam of the beam combining system input 154 emerging from an overlap region of the from the angular dispersive optic with a common direction of propagation thereby forming the combined output beam 160. In the embodiment depicted in FIG. 1, the wavelength-angle dispersion function (i.e. the relationship, defined for a range of wavelengths, between the wavelength of a beam and the difference between the beam's angles of incidence and transmission with respect to the optic) imparted by the angular dispersive optic 115 is identical to the wavelength-angle dispersion function imparted by the angular dispersive beam combining optic 122. Therefore, for each wavelength in the range of wavelengths for which the wavelength-angle dispersion function is defined, the difference between the angle of incidence and the angle of transmission of a beam will be the same with respect to both the angular dispersive optic 115 of the feedback generation system 103 and the angular dispersive beam combining optic 122.

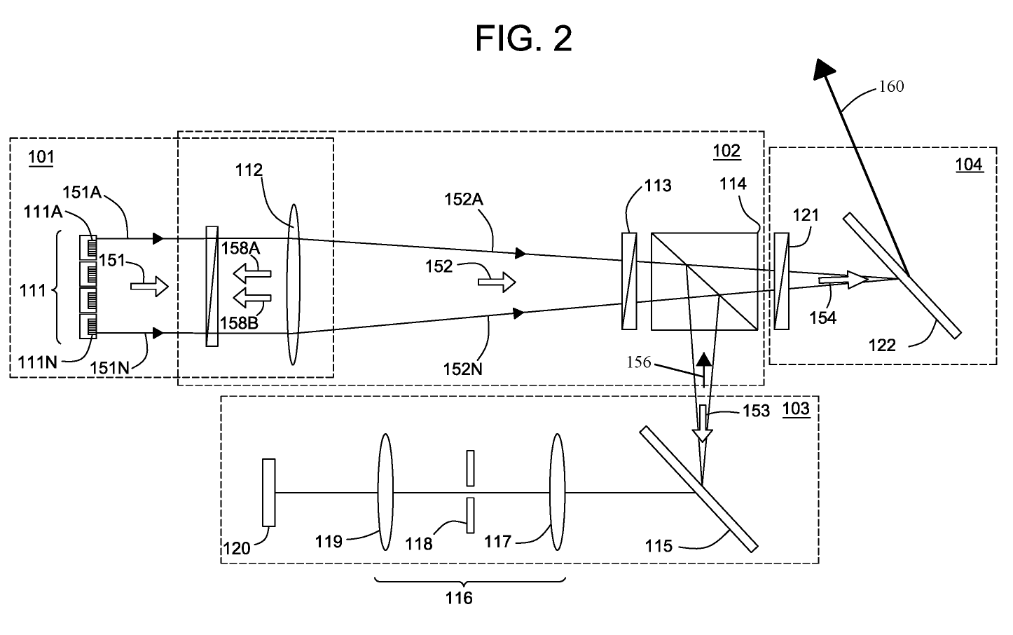

FIG. 2 illustrates an alternative apparatus for producing, via DWBC techniques, a single, multi-wavelength output laser beam comprising a plurality of spatially and directionally overlapped beams that each has a narrow wavelength spectrum. The embodiment illustrated in FIG. 2 is very similar to the embodiment illustrated in FIG. 1 and contains all of the same components. The components of the embodiment illustrated in FIG. 2 perform the same functions as those performed by the corresponding components of the embodiment illustrated in FIG. 1. However, in the embodiment illustrated in FIG. 2, the birefringent optic 113 is disposed in the optical path between the laser source 111 and the position-to-angle transform optic 112. Therefore, in the embodiment depicted in FIG. 2, the birefringent optic 113 alters the polarization state of the of the laser source output 151 before the position-angle-transform optic 112 transforms the position spectrum of the laser source output 151 into an angular spectrum.

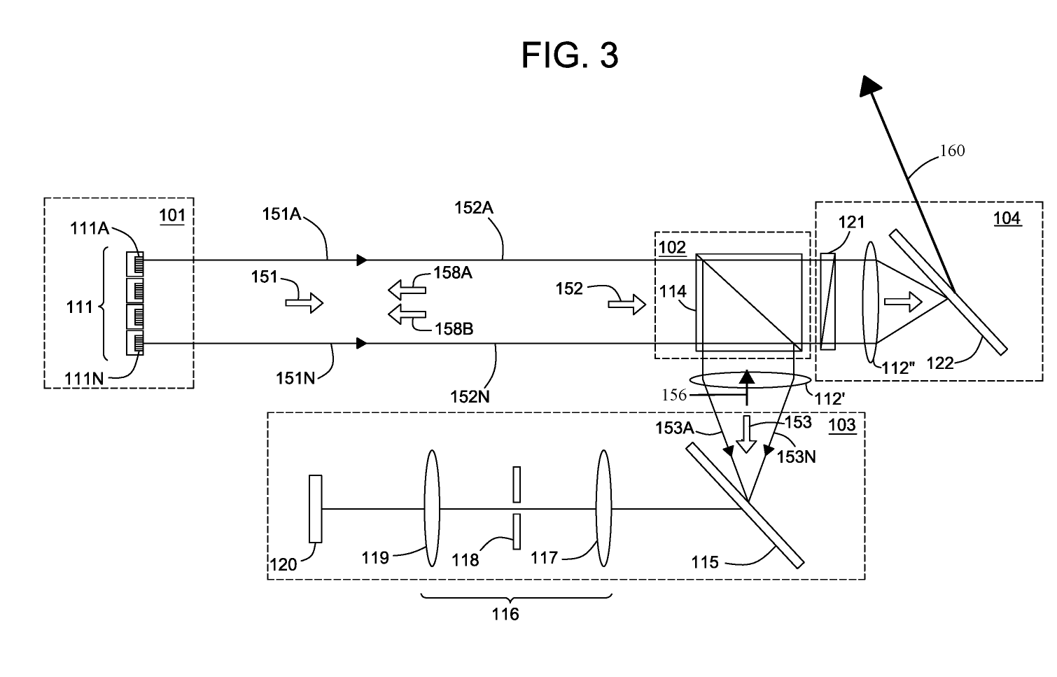

FIG. 3 illustrates an additional alternative apparatus for producing, via DWBC techniques, a single, multi-wavelength output laser beam comprising a plurality of spatially and directionally overlapped beams that each has a narrow wavelength spectrum. The embodiment illustrated in FIG. 3 is very similar to the embodiment illustrated in FIG. 1 and contains nearly all of the same components as the embodiment illustrated in FIG. 1. Furthermore, the components of the embodiment illustrated in FIG. 3 perform the same functions as those performed by the corresponding components of the embodiment depicted in FIG. 1. However, in the embodiment depicted in FIG. 3, the position-to-angle transform optic 112 is replaced with two separate but identical position-to-angle transform optics 112A and 112B. In the embodiment depicted in FIG. 3, the position-to-angle transform optic 112A transforms a position spectrum of the feedback generation system input 153 into an angular spectrum with respect to the angular dispersive optic 115, i.e. the position-to-angle transform optic 112A converts, for each constituent beam of the feedback generation system input 153, a position at which the constituent beam is incident upon the position-to-angle transform optic 112A to an angle of incidence with respect to the angular dispersive optic 115. Similarly, the position-to-angle transform optic 112B transforms a position spectrum of the beam combining system input 154 into an angular spectrum with respect to the angular dispersive beam combining optic 122, i.e. the position-to-angle transform optic 112B converts, for each constituent beam of the beam combining system input 154, a position at which the constituent beam is incident upon the position-to-angle transform optic 112B to an angle of incidence with respect to the angular dispersive beam combining optic 154.

FIGS. 4A and 4B illustrate configurations of laser sources for use in an external cavity laser apparatus wherein the laser sources are arrays of diode lasers formed from horizontal stacks of diode bars. FIGS. 4A and 4B both illustrate laser sources that are arrays of m·N diode lasers formed from a horizontal stack of N diode bars that each has m individual diode laser emitters. The configurations of the laser sources depicted in FIGS. 4A and 4B may be any of a geometrically stacked configuration (a geometric stack), an optically stacked configuration (an optical stack), or any other means of configuring a plurality of beams as depicted in FIGS. 4A and 4B. In the configuration illustrated in FIG. 4A, each of the m individual emitters of array of diode lasers 400A has a slow axis that is parallel to the direction of horizontal stacking. When the combining axis is parallel to the slow axis of the emitters, the profile of a combined output beam produced by a DWBC laser apparatus having a laser source configured as the array of diode lasers 400A is depicted as element 401A. In the configuration illustrated in FIG. 4B, each of the m individual emitters of array of diode lasers 400B has a fast axis that is parallel to the direction of horizontal stacking. When the combining axis is parallel to the slow axis of the emitters, the profile of a combined output beam produced by a DWBC laser apparatus having a laser source configured as the array of diode lasers 400B is depicted as element 401B. However, the configuration illustrated in FIG. 4A can produce a combined output beam with profile 401B and the configuration illustrated in FIG. 4B can produce a combined output beam with profile 401A through the utilization of suitable transformation optics, e.g. a beam rotator.

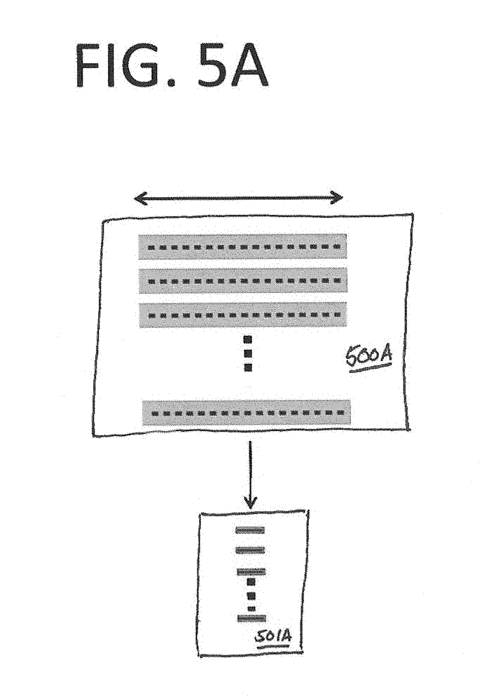

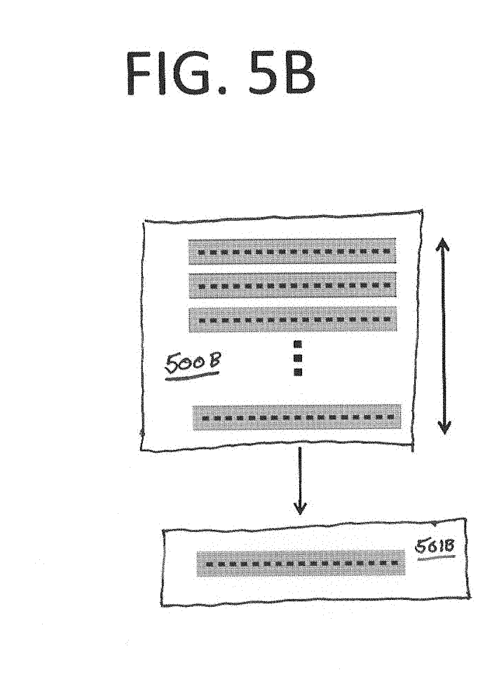

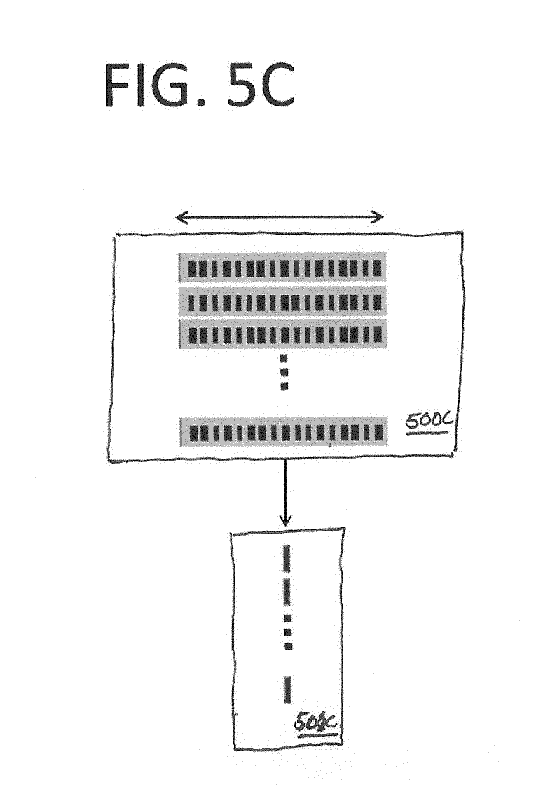

FIGS. 5A, 5B, and 5C illustrate configurations of laser sources for use in an external cavity laser apparatus wherein the laser sources are arrays of diode lasers formed from vertical stacks of diode bars. FIGS. 5A, 5B, and 5C all illustrate laser sources that are arrays of m·N diode lasers formed from a vertical stack of N diode bars that each has m individual diode laser emitters. The configurations of the laser sources depicted in FIGS. 5A, 5B, and 5C may be any of a geometrically stacked configuration (a geometric stack), an optically stacked configuration (an optical stack), or any other means of configuring a plurality of beams as depicted in FIGS. 5A, 5B, and 5C. In the configuration illustrated in FIG. 5A, each of the m individual emitters of array of diode lasers 500A has a slow axis that is perpendicular to the direction of vertical stacking. When the combining axis is parallel to the slow axis of the emitters, the profile of a combined output beam produced by a DWBC laser apparatus having a laser source configured as the array of diode lasers 500A is depicted as element 501A. In the configuration illustrated in FIG. 5B, each of the m individual emitters of array of diode lasers 500B has a fast axis that is parallel to the direction of vertical stacking. When the combining axis is parallel to the fast axis of the emitters, the profile of a combined output beam produced by a DWBC laser apparatus having a laser source configured as the array of diode lasers 500B is depicted as element 501B. In the configuration illustrated in FIG. 5C, each of the m individual emitters of array of diode lasers 500C has a fast axis that is perpendicular to the direction of vertical stacking. When the combining axis is parallel to the fast axis of the emitters, the profile of a combined output beam produced by a DWBC laser apparatus having a laser source configured as the array of diode lasers 500C is depicted as element 501C. However, the various configurations illustrated in FIGS. 5A-C can produce combined output beams with various different profiles through the utilization of suitable transformation optics, e.g. beam rotators. Such transformation optics and the transformations they are able to produce are shown, e.g., in U.S. Pat. No. 8,553,327.

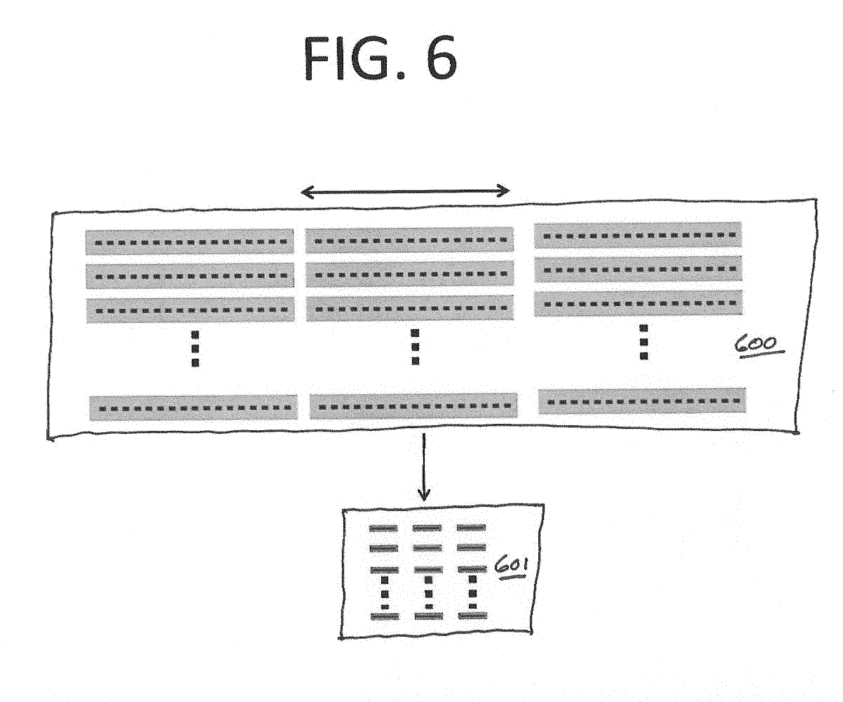

FIG. 6 illustrates a configuration of a laser source for use in an external cavity laser apparatus wherein the laser source is an array of diode lasers formed from a two-dimensional stack of diode bars. FIG. 6 illustrates a laser source that is an array 600 of three columns of N diode bars that each has m individual emitters. In other words, the array 600 includes a horizontal stack of three vertical stacks of N diode bars, or alternatively, the array 600 includes a vertical stack of N horizontal stacks of three diode bars. In the configuration illustrated in FIG. 6, each of the 3·m·N individual diode emitters has a fast axis that is parallel to the direction of horizontal stacking. The configurations of the laser sources depicted in FIG. 6 may be any of a geometrically stacked configuration (a geometric stack), an optically stacked configuration (an optical stack), or any other means of configuring a plurality of beams as depicted in FIG. 6. When the combining axis is parallel to the slow axis of the emitters, the profile of a combined output beam produced by a DWBC laser apparatus having a laser source configured as the array 600 is depicted as element 601. However, the configuration illustrated in FIG. 6 can produce combined output beams with different profiles if the emitters have their fast axis aligned perpendicular to the direction of horizontal stacking, i.e. parallel to the direction of vertical stacking. Furthermore, the configuration illustrated in FIG. 6 can produce combined output beams with various different profiles through the utilization of suitable transformation optics, e.g. beam rotators. Such transformation optics and the transformations they are able to produce are shown, e.g., in U.S. Pat. No. 8,553,327.

It is thus contemplated that other implementations of the invention may differ in detail from foregoing examples. As such, all references to the invention are intended to reference the particular example of the invention being discussed at that point in the description and are not intended to imply any limitation as to the scope of the invention more generally. All language of distinction and disparagement with respect to certain features is intended to indicate a lack of preference for those features, but not to exclude such from the scope of the invention entirely unless otherwise indicated.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. An external cavity laser apparatus comprising:
a plurality of beam emitters that collectively emit a plurality of external cavity input beams each having a primary component with an initial linear polarization state;
an angular dispersive output beam combining optic;
a beam splitter disposed in an optical path from the plurality of beam emitters to the angular dispersive output beam combining optic, the beam splitter being configured to extract, from the plurality of external cavity input beams, a plurality of first extracted component beams and to reflect the plurality of first extracted component beams into a feedback branch, the feedback branch being disposed external to the optical path from the plurality of beam emitters to the angular dispersive output beam combining optic;
a birefringent optic disposed in an optical path between the plurality of beam emitters and the beam splitter;
a first position-to-angle transform optic disposed in the optical path from the plurality of beam emitters to the angular dispersive output beam combining optic, the first position-to-angle transform optic configured to impart an angular spectrum on the plurality of first extracted component beams by imparting, upon each of the plurality of first extracted component beams, an angle of incidence with respect to a feedback branch angular dispersive optic that differs from angles of incidence of others of the plurality of first extracted component beams with respect to the feedback branch angular dispersive optic;
the feedback branch angular dispersive optic, which is disposed in the feedback branch, having a first wavelength-dependent angular dispersion function, the feedback branch angular dispersive optic being configured to transform the angular spectrum of the first extracted component beams into a wavelength-dependent angular spectrum of the first extracted component beams determined by the first wavelength-dependent angular dispersion function, and
a reflective element disposed in the feedback branch and configured to reflect the plurality of first extracted component beams back through the beam splitter and the birefringent optic such that at least a portion of the plurality of first extracted component beams is reflected into the plurality of beam emitters as a plurality of orthogonal feedback component beams having a polarization state that is orthogonal to the initial linear polarization state.

2. The apparatus of claim 1, wherein the plurality of beam emitters is a plurality of diode beam emitters arranged in a bar.

3. The apparatus of claim 1, wherein the plurality of beam emitters is a plurality of diode beam emitters arranged in an array.

4. The apparatus of claim 3, wherein the array is formed from one of a plurality of diode bars configured in a vertical stack, a plurality of diode bars configured in a horizontal stack, or two-dimensional array of diode bars.

5. The apparatus of claim 1, wherein the first position-to-angle transform optic is configured to impart the angular spectrum on the plurality of first extracted component beams by imparting a corresponding angular spectrum upon the plurality of external cavity input beams.

6. The apparatus of claim 1, wherein the beam splitter is further configured to extract from the plurality of external cavity input beams a plurality of second extracted component beams and to direct the plurality of second extracted component beams into a beam combining branch.

7. The apparatus of claim 6, further comprising a polarizing optic configured to rotate the polarization of each of the plurality of second extracted component beams.

8. The apparatus of claim 6, wherein the beam combining branch comprises the angular dispersive output beam combining optic, the angular dispersive output beam combining optic having a second wavelength-dependent angular dispersion function and configured to impart a wavelength-dependent angular spectrum determined by the second wavelength-dependent angular dispersion function on the plurality of second extracted component beams.

9. The apparatus of claim 8, wherein the angular dispersive output beam combining optic produces a combined output beam by transmitting or reflecting the plurality of second extracted component beams from an overlap region with a common direction of propagation.

10. The apparatus of claim 8, wherein the first wavelength-dependent angular dispersion function is identical to the second wavelength-dependent angular dispersion function.

11. The apparatus of claim 1, wherein the birefringent optic is a first half wave plate configured to rotate the polarization state of each of the plurality of external cavity input beams to produce a plurality of altered input beams each having a first altered input beam component with a polarization state that is orthogonal to the initial linear polarization state and a second altered input beam component with a polarization state that is parallel to the initial linear polarization state; and
wherein the beam splitter is a polarizing beam splitter configured to produce the plurality of first extracted component beams by extracting, from each of the plurality of altered input beams, the first altered input beam component, and to reflect the first extracted component beam into the feedback branch.

12. The apparatus of claim 8, further comprising:
a spatial filtering assembly configured to transmit, as a plurality of feedback beams, only a portion of the plurality of first extracted component beams that correspond to a portion of the wavelength-dependent angular spectrum imparted.

13. The apparatus of claim 9, wherein the spatial filtering assembly comprises:
a first position-to-angle transform optic;
a second position-to-angle transform optic; and
an aperture disposed between the first position-to-angle transform optic and the second position-to-angle transform optic.

14. The apparatus of claim 1, wherein the plurality of orthogonal feedback component beams have an optical power that is greater than about 50% of an optical power of the plurality of first extracted component beams.

15. The apparatus of claim 1, wherein the plurality of orthogonal feedback component beams have an optical power that is greater than about 85% of an optical power of the plurality of first extracted component beams.

16. The apparatus of claim 1, wherein the plurality of orthogonal feedback component beams have an optical power that is greater than about 90% and less than about 98% of an optical power of the plurality of first extracted component beams.

17. A method for stabilizing the wavelengths of a plurality of input beams collectively emitted by a plurality of emitters, each of the plurality of input beams having a primary component with an initial linear polarization state, the method comprising:
directing the plurality of input beams through a birefringent optic;
extracting, from the plurality of input beams by a beam splitter disposed in an optical path from the plurality of emitters to an angular dispersive output beam combining optic, a plurality of extracted component beams;
reflecting the plurality of extracted component beams into a feedback branch, the feedback branch being disposed external to the optical path from the plurality of beam emitters to the angular dispersive output beam combining optic;
imparting an angular spectrum on the plurality of extracted component beams by imparting, upon each of the plurality of extracted component beams, an angle of incidence with respect to a feedback branch angular dispersive optic that differs from angles of incidence of others of the plurality of extracted component beams with respect to the feedback branch angular dispersive optic;
directing the plurality of extracted component beams at the feedback branch angular dispersive optic such that the feedback branch angular dispersive optic transforms the angular spectrum of the plurality of extracted component beams into a wavelength-dependent angular spectrum of the plurality of extracted component beams;
directing the plurality of extracted component beams through a wavelength selective optic and through the birefringent optic so as to provide a plurality of feedback beams that each includes a component that has a polarization state that is orthogonal to the initial linear polarization state of the plurality of input beams; and
directing the plurality of feedback beams into the plurality of emitters.

18. The method of claim 17, wherein directing the plurality of input beams through the birefringent optic rotates the polarization state of each of the plurality of input beams so as to provide a plurality of altered input beams each having a first altered input beam component with a polarization state that is orthogonal to the initial linear polarization state and a second altered input beam component with a polarization state that is parallel to the initial linear polarization state; and
wherein extracting from the plurality of input beams a plurality of extracted component beams comprises extracting from each of the plurality of altered input beams the first altered input beam component so as to provide the plurality of extracted component beams.

19. The method of claim 18, wherein the directing the plurality of extracted component beams through the feedback branch comprises:
directing the plurality of extracted component beams having the wavelength-dependent angular spectrum at the spatial filtering element; and
transmitting, as the plurality of feedback beams, a portion of the plurality of extracted component beams that corresponds to a portion of the wavelength-dependent angular spectrum.

20. A method for producing a combined output beam formed from a plurality of beam combining input beams extracted from a plurality of linearly-polarized laser source output beams collectively emitted by a plurality of emitters, each of the plurality of laser source output beams having a primary component with an initial linear polarization state, the method comprising:
directing the plurality of input beams through a birefringent optic;
extracting from the plurality of input beams, by a beam splitter disposed in an optical path from the plurality of emitters to an angular dispersive output beam combining optic, a plurality of extracted component beams and the plurality of beam combining input beams;
reflecting the plurality of extracted component beams into a feedback branch disposed outside the optical path from the plurality of emitters to the angular dispersive output beam combining optic;
imparting an angular spectrum on the plurality of extracted component beams by imparting, upon each of the plurality of extracted component beams, an angle of incidence with respect to a feedback branch angular dispersive optic that differs from angles of incidence of others of the plurality of extracted component beams with respect to the feedback branch angular dispersive optic;
directing the plurality of extracted component beams through the feedback branch angular dispersive optic such that the feedback branch angular dispersive optic transforms the angular spectrum of the plurality of extracted component beams into a wavelength-dependent angular spectrum of the plurality of extracted component beams;
directing the plurality of extracted component beams through a wavelength selective optic and through the birefringent optic so as to provide a plurality of feedback beams that each includes a component that has a polarization state that is orthogonal to the initial linear polarization state of the plurality of input beams;
directing the plurality of feedback beams into the plurality of emitters; and
providing the combined output beam by directing the plurality of beam combining input beams at the angular dispersive output beam combining optic such that each of the plurality of beam combining input beams emerges from an overlap region of the angular dispersive beam combining optic with a common direction of propagation.

21. The system of claim 1, wherein the feedback branch angular dispersive optic is disposed relative to the position-to-angle transform optic such that a preferred resonant mode component of each respective first extracted component beam emerges from the angular dispersive optic with a common direction of propagation and a wavelength that is dependent on the angle of incidence with respect to the feedback branch angular dispersive optic imparted on such respective first extracted component beam by the position-to-angle transform optic.

22. The system of claim 1, wherein the birefringent optic is configured to adjust a fraction of optical power of the plurality of external cavity input beams the beam splitter is configured to extract as the plurality of first extracted component beams.
